(19) United States
(12) Patent Application Publication
(10) Pub. No.: US 2026/0088807 A1
(43) Pub. Date: Mar. 26, 2026

(54) DECISION FEEDBACK EQUALIZER (DFE)

(71) Applicants: Santosh Kumar, Ttlangana (IN); Raghavendra Kulkarni, Gubbalala (IN); Gunjan Mandal, Bangalore (IN)

(72) Inventors: Santosh Kumar, Ttlangana (IN); Raghavendra Kulkarni, Gubbalala (IN); Gunjan Mandal, Bangalore (IN)

(21) Appl. No.: 18/897,397

(22) Filed: Sep. 26, 2024

(51) Int. Cl. H03K 3/037; H03K 5/24; H04L 25/03

(52) U.S. Cl. CPC H03K 3/037; H03K 5/24; H04L 25/03057

(57) ABSTRACT

A decision feedback equalizer (DFE) includes a first sample-and-hold (SH) circuit to generate a first voltage signal pair based on an input voltage signal, a second SH circuit to generate a second voltage signal pair based on the input voltage signal, and a first comparator circuit to generate a first output voltage signal based on the first voltage signal pair, a first feedback signal, and a second feedback signal. The first SH circuit generates the first voltage signal pair at least based on a first clock signal. The first SH circuit is configured to limit the first clock signal to at least a 25% duty cycle based on limiting a conversion phase delay associated with the first clock signal, narrowing a reset phase of the first clock signal, and generating a hold phase of the first clock signal based on the narrowing of the reset phase.

### BACKGROUND

For short channel applications such as chip-to-chip or die-to-die, there is a need for high speed, low power, and low area Interface, where a lot of single-ended channels run together. An optimal DFE-based solution can be sufficient to address the inter-symbol interference (ISI) of short channels. However, implementing a DFE-based solution with minimal die area, low power, and increased processing and communication speed is challenging.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings listed below.

FIG. 1 is a block diagram of a 2-tap decision feedback equalizer (DFE), in accordance with some embodiments.

FIG. 2 illustrates graphs associated with DFE timing, in accordance with some embodiments.

FIG. 3 is a block diagram of an example comparator used by the DFE of FIG. 1, in accordance with some embodiments.

FIG. 4 is a block diagram of actual and dummy capacitive digital-to-analog converters (DACs) connected to integration nodes X and Y in the DFE of FIG. 1, in accordance with some embodiments.

FIG. 5 is a block diagram of the actual capacitive DAC of FIG. 4, in accordance with some embodiments.

FIG. 6 is a block diagram of the dummy capacitive DAC of FIG. 4, in accordance with some embodiments.

FIG. 7 is a flow diagram of an example method for manufacturing an equalizer circuit, in accordance with some embodiments.

FIG. 8 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

As used herein, the term “IO” indicates input/output. As used herein, the term “R-C” indicates resistance and capacitance. As used herein, the term “Rx” indicates receiver (or receive). As used herein, the term “Tx” indicates transmitter (or transmit). As used herein, the term “TRX” indicates transceiver. As used herein, the term “UCIe” indicates Universal Chiplet Interconnect Express. As used herein, the term “Vref” indicates reference voltage. As used herein, the term “Vin” indicates input voltage. As used herein, the terms “serially coupled,” “serially connected,” and “connected in series” are synonymous to each other and indicate a serial connection between two or more components/circuits where the serial connection can be based on a direct or indirect electrical connection between the two or more components/circuits. As used herein, the terms “parallel coupled,” “parallel connected,” and “connected in parallel” are synonymous to each other and indicate a parallel connection between two or more components/circuits where the parallel connection can be based on a direct or indirect electrical connection between the two or more components/circuits.

The disclosed techniques include configurations for two-tap, two-path DFE, where each path operates at, e.g., 8 GHz alternatively to achieve a 16 Gbps data rate. The disclosed DFE solution is a comparator design with inherently controllable offsets as DFE weights. The solution includes a capacitive DAC to implement these controllable offsets while achieving low area, low power, and high-speed performance. The disclosed DFE block can be used as an interface in a receiver front-end circuit that is connected to a bond pad. The disclosed DFE includes a comparator circuit with a capacitive (cap) DAC connected at the regeneration node. The cap DAC can be implemented using an array of transistors connected to a specific structure, as shown in the figures. This solution provides low power and low area equalization techniques and circuit implementation while meeting the bandwidth performance per channel.

Novel aspects of the disclosed techniques include:
(a) Implementation of a 25% clock at the sampler to meet the first DFE tap timing without a latch.
(b) Implementation of a comparator without additional latch to meet the IUI timing and hence improve the feedback loop timing of DFE.
(c) Implementation of DFE tap weights through cap DACs as opposed to implantation of conventional voltage/current reference DACs, which consume power and area.
(d) Cap DAC DFE tap weights are implemented differentially, with one arm being a dummy cap DAC (offering minimum capacitance), whereas the other arm has an actual cap DAC (this improves the resolution of the cap DAC for a given range).

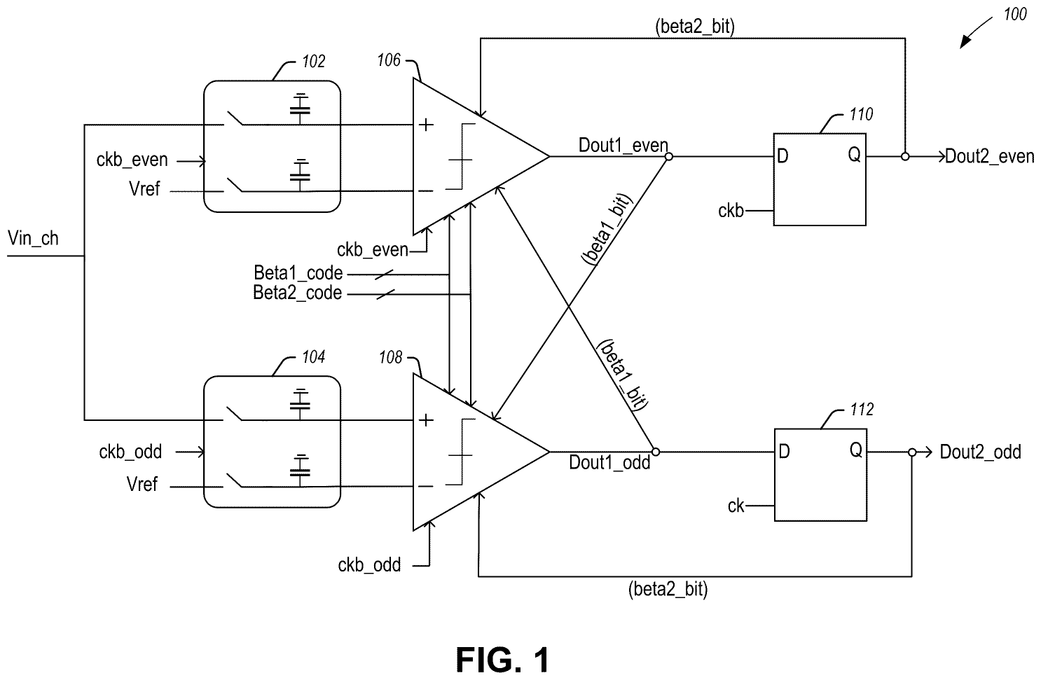

FIG. 1 is a block diagram of a 2-tap decision feedback equalizer (DFE), in accordance with some embodiments. Referring to FIG. 1, DFE 100 comprises a first sample-and-hold (SH) circuit 102, a second SH circuit 104, a first comparator circuit 106, a second comparator circuit 108, a first flip-flop (FF) circuit 110, and a second FF circuit 112. The designations of the input signals, output signals, and clock signals are indicated in FIG. 1.

As seen in FIG. 1, each comparator circuit enables implementation of a 2-tap DFE circuit, where the output of the corresponding FF circuit and the output of the other comparator are used as two feedback signals. For example, comparator circuit 106 uses feedback bit beta2_bit (from the output of FF circuit 110) and feedback bit beta1_bit (from the output of comparator circuit 108. Similarly, comparator circuit 108 uses feedback bit beta2_bit (from the output of FF circuit 112) and feedback bit beta1_bit (from the output of comparator circuit 106)

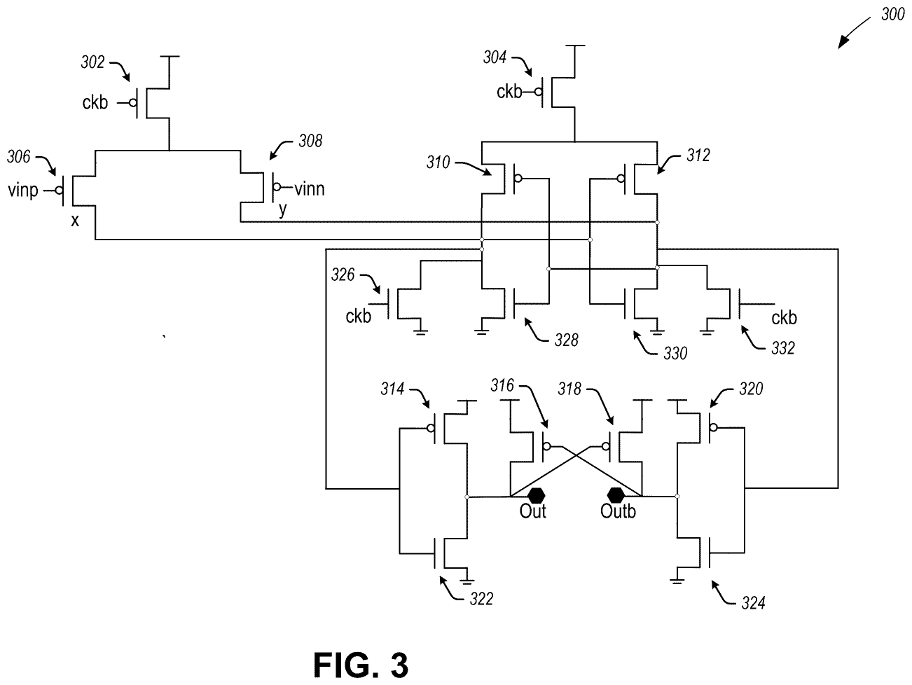

Additionally, each of the comparator circuits 106 and 108 receives signals beta1_code and beta2_code as DFE tap weights codes (corresponding to tap-1 and tap 2 respectively) that can be used by the cap DACs in each comparator circuit to adapt the circuit to a given channel loss profile. A more detailed description of the configuration of each comparator circuit is provided in connection with FIGS. 3-6.

In some aspects, DFE 100 can be used as a very low power, low area two tap DFE solution that enables 16 Gbps data rate for short channel applications such as chip-to-chip or die-to-die interfaces.

As illustrated in FIG. 1, DFE 100 includes two processing paths (each including a SH circuit, a comparator circuit, and an FF circuit), each operating at half the input data rate. In FIG. 1, the two paths are referred to as an even path and an odd path, each operating at an 8 GHz clock on alternate phases so that the output of this circuit constitutes inherent de-multiplexing.

As explained above, each path includes a SH circuit, a comparator with Tap1 and Tap2 weight controls (e.g., beta1_code and beta2_code), and Dout1, Dout2 (previous bit and second previous bit) feedback input. Each FF circuit generates the second previous bit and acts as an output re-timing circuit.

The sampled input of the comparator will have the ISI error components from the previously transmitted bits, which is called post-cursor. The disclosed DFE scheme removes the post-cursor effect from previous bits. In the DFE 100, the last two previous bits, Dout1 and Dout2 impact, are nullified by inducing controlled offsets in the comparator as tap weights by setting proper values of beta1_code beta2_code. For chip-to-chip channel lengths, mostly 2-tap feedback is sufficient to minimize the ISI effect due to channel loss.

In some aspects, the SH circuit and the comparator circuit together act as feedback summer and sampler circuits of DFE with a positive regeneration circuit inside the comparator.

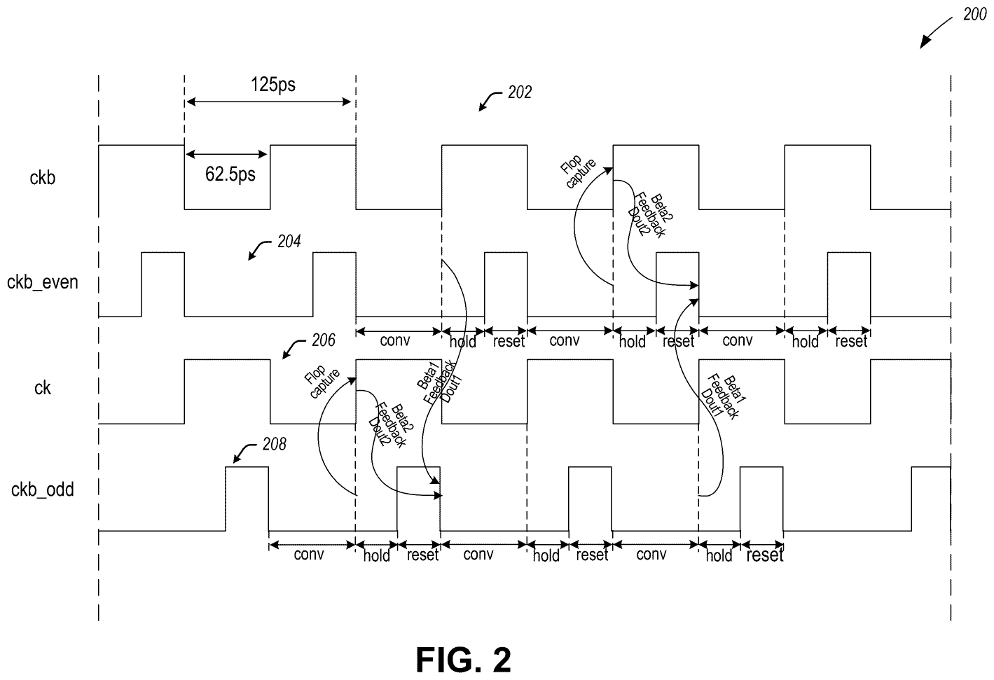

FIG. 2 illustrates graphs 202, 204, 206, and 208 associated with DFE timing 200, in accordance with some embodiments. As it can be seen from the timing diagrams in FIG. 2, say for even path (ckb_even), before the start of the conversion of even comp (ckb_even going low), Dout1 that is feedback from odd path conversion should be available. This is the critical path, and its delay may not exceed 62.5 ps. To reduce the delay of this critical path, the latch (the FF circuit) and associated delay of the latch on the comparator output is avoided; instead, the reset phase is narrowed to accommodate an additional hold phase. This helped contain critical path delays of less than 62.5 ps, even in worst-case scenarios.

Conversion phase delay is limited by small differential input in the order of a few mV, whereas the reset phase could be narrowed by the switches operating with full VDD as overdrive voltages. This helped create the hold phase.

The hold phase of the odd path during the initial part of the conversion phase of the even path helps set the right direction before triggering regeneration inside the comparator. Hence, the reset phase in the later part does not impact the comparator's decision.

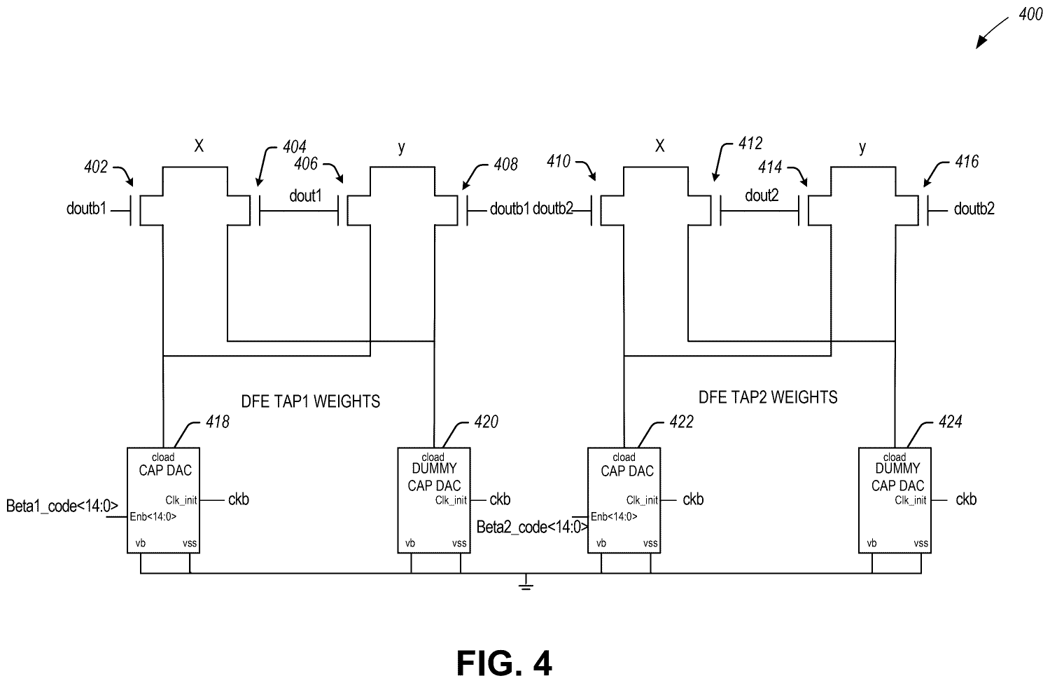

FIG. 3 is a block diagram of an example sample-and-hold circuit and comparator together used by the DFE of FIG. 1, in accordance with some embodiments. Referring to FIG. 3, comparator 300 includes PMOS transistors 302, 304, 306, 308, 310, 312, 314, 316, 318, and 320 connected as illustrated in FIG. 3. Comparator 300 further includes NMOS transistors 326, 328, 330, 332, 322, and 324 connected as illustrated in FIG. 3. FIG. 3 also illustrates the designation of the input signals, output signals, and clock signals, as well as the location of integration nodes X and Y, which can be used to couple the cap DACs (e.g., as illustrated in FIG. 4).

FIG. 4 is a block diagram 400 of actual and dummy capacitive digital-to-analog converters (DACs) connected to integration nodes X and Y in the DFE of FIG. 1, in accordance with some embodiments. Referring to FIG. 4, the actual cap DAC 418 is coupled to integration nodes X and Y via corresponding NMOS transistors 402 and 406. Dummy cap DAC 420 is coupled to integration nodes X and Y via corresponding NMOS transistors 404 and 408.

Actual cap DAC 422 is coupled to integration nodes X and Y via corresponding NMOS transistors 410 and 414. Dummy cap DAC 424 is coupled to integration nodes X and Y via corresponding NMOS transistors 412 and 416.

Depending on the Dout1 polarity, actual and dummy cap DAC connections to the integration nodes are exchanged. In some aspects, the strength of the cap connected to the node will depend on the beta1_code. The same is the case for Dout2, but the beta2_code controls it.

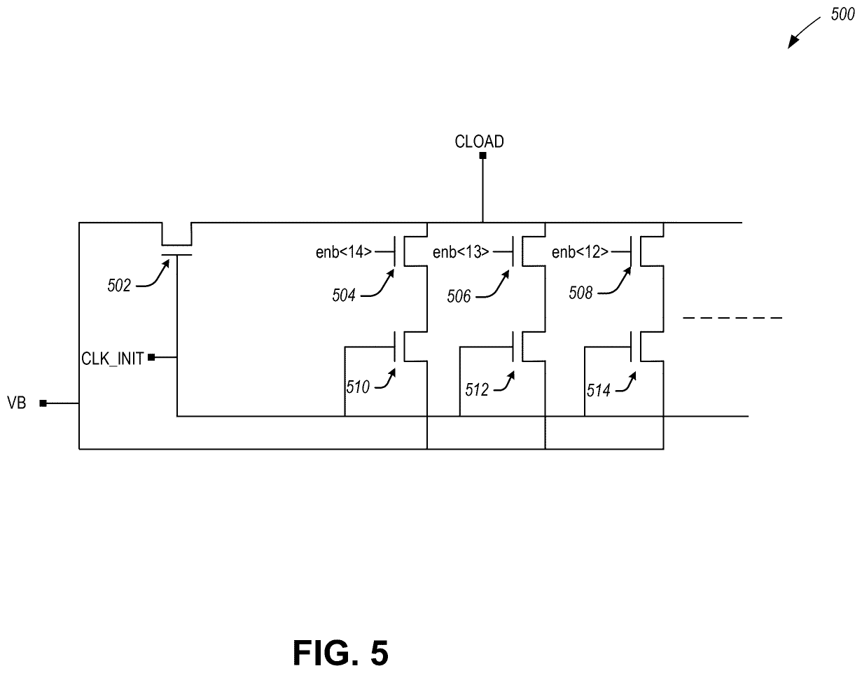

FIG. 5 is a block diagram of the actual capacitive DAC of FIG. 4, in accordance with some embodiments. Referring to FIG. 5, the actual cap DAC 500 includes a first set of NMOS transistors 502, 510, 512, 514, . . . , and a second set of NMOS transistors 504, 506, 508, . . . , connected as illustrated in FIG. 5. The second set of NMOS transistors 504, 506, 508, . . . can be used to receive the tap codes (e.g., beta1_code or beta2_code).

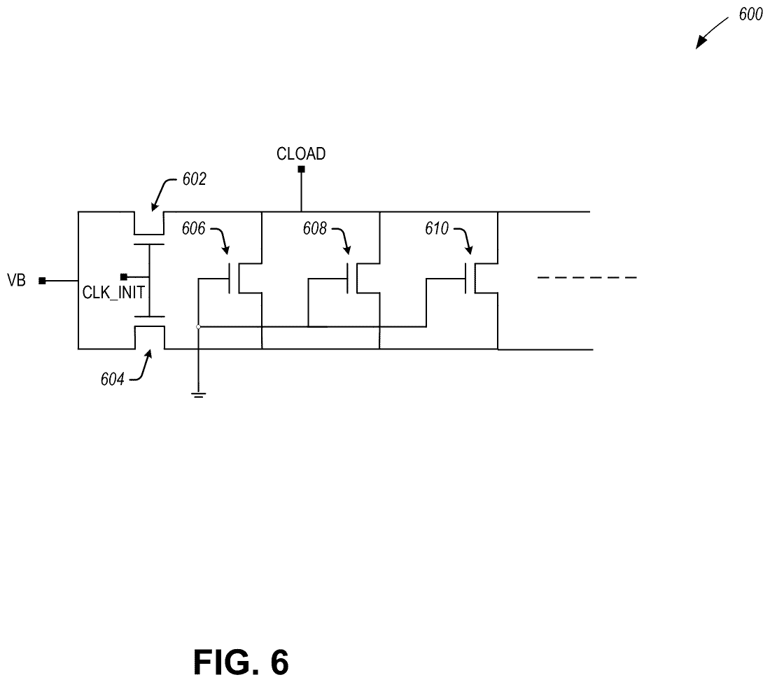

FIG. 6 is a block diagram of the dummy capacitive DAC of FIG. 4, in accordance with some embodiments. Referring to FIG. 6, the dummy cap DAC 600 includes NMOS transistors 602, 604, 606, 608, 610, . . . , connected as illustrated in FIG. 6.

As can be seen from FIG. 5 and FIG. 6, cap DACs can be built using sufficiently smaller transistors operating with a floating node on one end and the other end connected to the integration node. Transistors driven by clk_init are only for initialization; during conversion, they will be in an OFF state.

When the control bit is ON, the transistor will offer a total channel cap. The actual delta cap seen between integration nodes X and Y is the channel cap multiplied by the number of control bits that are ON.

The disclosed cap DAC structure implemented of minimalist cap units not only gives the benefit of improved critical path delay but also results in a significant power reduction while maintaining sufficient linearity.

In some aspects, the disclosed cap DAC is implemented using MOS devices. For the targeted chip-to-chip channel, the additional clk-to-q (conversion time) of the sampler is approximately 15 ps (worst case pvt) due to the cap DAC. A worst-case conversion time can be 48 ps. The sampler may not have a 2nd latch stage to reduce the overall clk-to-q delay. The value of the total cap DAC capacitor can be, e.g., 20 fF and 12 f for the two stages, which can be sufficient for the required DFE co-efficient for channel loss up to 8 dB. The beta1_code requirement can be 27 mV, and the beta2_code requirement can be 18 mV.

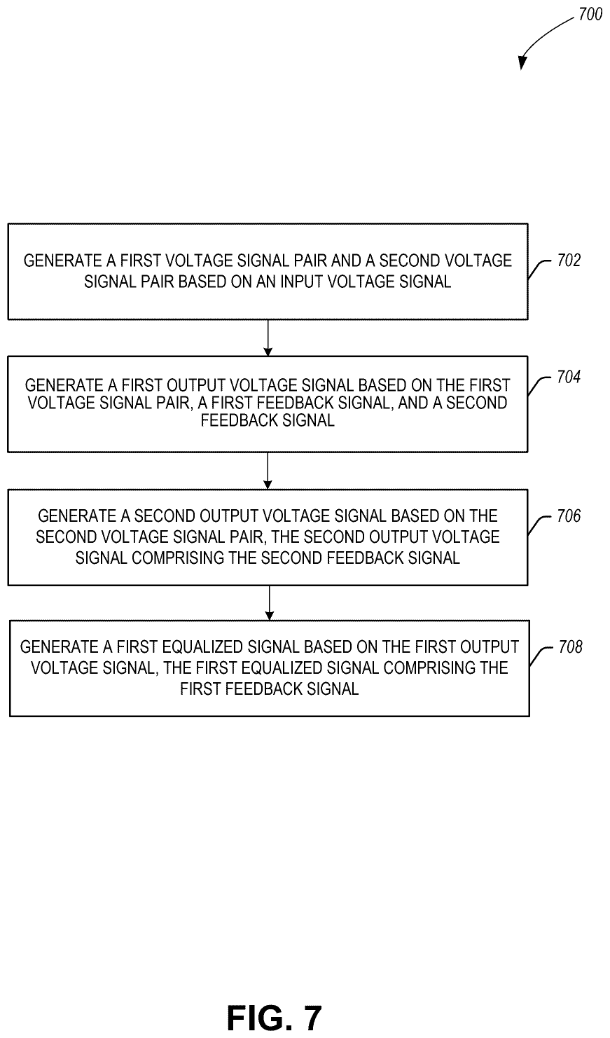

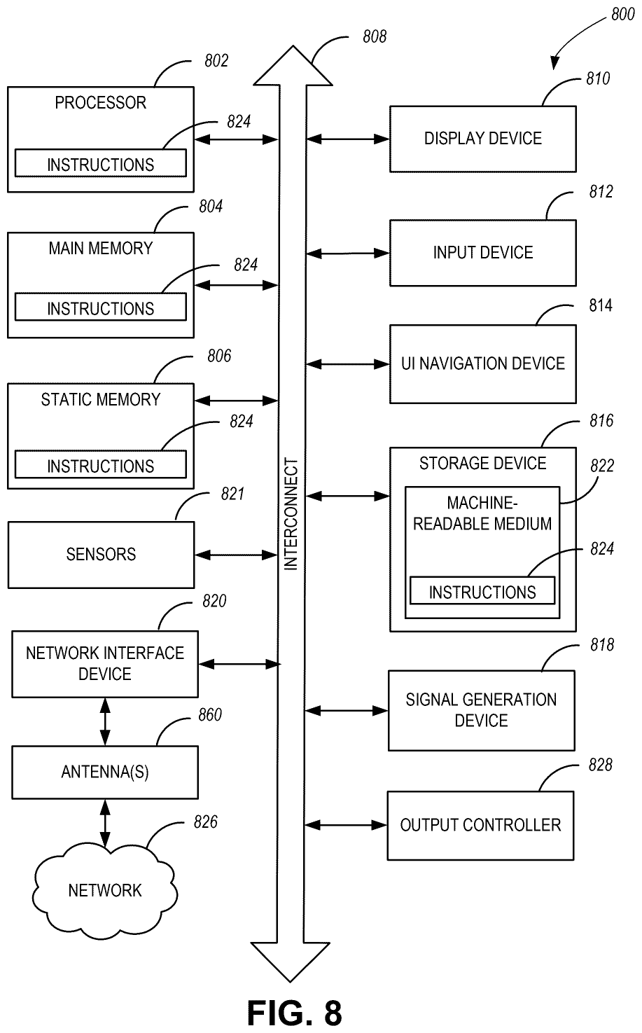

FIG. 7 is a flow diagram of an example method 700 for manufacturing an equalizer circuit, in accordance with some embodiments. Referring to FIG. 7, method 700 includes operations 702, 704, 706, and 708, which may be executed by a processor, an embedded controller, a receiver circuit, a transceiver circuit, or another processor of a computing device (e.g., hardware processor 802 of machine 800 illustrated in FIG. 8, which can include one or more of the circuits discussed in connection with FIGS. 1-6). In some embodiments, one or more of the circuits discussed in connection with FIGS. 1-6 can perform the functionalities (or include the configurations or circuitry) associated with FIG. 7, as well as one or more of the examples listed below.

At operation 702, DFE 100 generates a first voltage signal pair (at the output of SH circuit 102) and a second voltage signal pair (at the output of SH circuit 104) based on an input voltage signal.

At operation 704, DFE 100 generates a first output voltage signal (Dout1_even) based on the first voltage signal pair, a first feedback signal (beta2_bit), and a second feedback signal (beta1_bit).

At operation 706, DFE 100 generates a second output voltage signal (Dou1_odd) based on the second voltage signal pair. The second output voltage signal includes the second feedback signal.

At operation 708, DFE 100 generates a first equalized signal (Dout2_even) based on the first output voltage signal. The first equalized signal includes the first feedback signal.

FIG. 8 illustrates a block diagram of an example machine 800 upon which any one or more of the techniques (e.g., methodologies) discussed herein may perform. In alternative embodiments, the machine 800 may operate as a standalone device or may be connected (e.g., networked) to other machines. In a networked deployment, machine 800 may operate in the capacity of a server machine, a client machine, or both in server-client network environments. In an example, machine 800 may function as a peer machine in a peer-to-peer (P2P) (or other distributed) network environment. The machine 800 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 800 may include a hardware processor 802 (e.g., a central processing unit (CPU), a graphics processing unit (GPU), a hardware processor core, or any combination thereof), a main memory 804, and a static memory 806, some or all of which may communicate with each other via an interlink (e.g., bus) 808. In some aspects, the main memory 804, the static memory 806, or any other type of memory (including cache memory) used by machine 800 can be configured based on the disclosed techniques or can implement the disclosed memory devices.

Specific examples of main memory 804 include Random Access Memory (RAM) and semiconductor memory devices, which may include, in some embodiments, storage locations in semiconductors such as registers. Specific examples of static memory 806 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 800 may further include a display device 810, an input device 812 (e.g., a keyboard), and a user interface (UI) navigation device 814 (e.g., a mouse). In an example, the display device 810, the input device 812, and the UI navigation device 814 may be a touchscreen display. The machine 800 may additionally include a storage device (e.g., drive unit or another mass storage device) 816, a signal generation device 818 (e.g., a speaker), a network interface device 820, and one or more sensors 821, such as a global positioning system (GPS) sensor, compass, accelerometer, or other sensors. The machine 800 may include an output controller 828, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 802 and/or instructions 824 may comprise processing circuitry and/or transceiver circuitry.

The storage device 816 may include a machine-readable medium 822 on which one or more sets of data structures or instructions 824 (e.g., software) embodying or utilized by any one or more of the techniques or functions described herein can be stored. Instructions 824 may also reside, completely or at least partially, within the main memory 804, within static memory 806, or the hardware processor 802 during execution thereof by machine 800. In an example, one or any combination of the hardware processor 802, the main memory 804, the static memory 806, or the storage device 816 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 822 is illustrated as a single medium, the term “machine-readable medium” may include a single medium or multiple media (e.g., a centralized or distributed database and/or associated caches and servers) configured to store instructions 824.

An apparatus of machine 800 may be one or more of a hardware processor 802 (e.g., a central processing unit (CPU), a graphics processing unit (GPU), a hardware processor core, or any combination thereof), a main memory 804 and a static memory 806, one or more sensors 821, a network interface device 820, one or more antennas 860, a display device 810, an input device 812, a UI navigation device 814, a storage device 816, instructions 824, a signal generation device 818, and an output controller 828. The apparatus may be configured to perform one or more of the methods and/or operations disclosed herein. The apparatus may be intended as a component of machine 800 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 800 and that causes machine 800 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 824 may further be transmitted or received over a communications network 826 using a transmission medium via the network interface device 820 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.8.4 family of standards, a Long Term Evolution (LTE) family of standards, a Universal Mobile Telecommunications System (UMTS) family of standards, peer-to-peer (P2P) networks, among others.

In an example, the network interface device 820 may include one or more physical jacks (e.g., Ethernet, coaxial, or phone jacks) or one or more antennas to connect to the communications network 826. In an example, the network interface device 820 may include one or more antennas 860 to wirelessly communicate using at least one single-input multiple-output (SIMO), multiple-input multiple-output (MIMO), or multiple-input single-output (MISO) techniques. In some examples, the network interface device 820 may wirelessly communicate using multiple-user MIMO techniques. The term “transmission medium” shall be taken to include any intangible medium that can store, encode, or carry instructions for execution by machine 800 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is an equalizer circuit comprising: a first sample-and-hold (SH) circuit comprising a first input terminal and a second input terminal, the first input terminal of the first SH circuit to receive an input voltage signal; a second SH circuit comprising a first input terminal and a second input terminal, the first input terminal of the second SH circuit to receive the input voltage signal; a first comparator circuit comprising a first input terminal coupled to a first output terminal of the first SH circuit and a second input terminal coupled to a second output terminal of the first SH circuit; a second comparator circuit comprising a first input terminal coupled to a first output terminal of the second SH circuit and a second input terminal coupled to a second output terminal of the second SH circuit; a first flip-flop (FF) circuit comprising a first input terminal coupled to an output terminal of the first SH circuit, and an output terminal coupled to a third input terminal of the first comparator circuit; and a second FF circuit comprising a first input terminal coupled to an output terminal of the second SH circuit, and an output terminal coupled to a third input terminal of the second comparator circuit.

In Example 2, the subject matter of Example 1 includes, wherein an output terminal of the first comparator circuit is coupled to a fourth input terminal of the second comparator circuit.

In Example 3, the subject matter of Example 2 includes, wherein an output terminal of the second comparator circuit is coupled to a fourth input terminal of the first comparator circuit.

In Example 4, the subject matter of Example 3 includes, wherein the first comparator circuit comprises a fifth input terminal to receive a first tap code and a sixth input terminal to receive a second tap code.

In Example 5, the subject matter of Example 4 includes, wherein the second comparator circuit comprises a fifth input terminal to receive the first tap code and a sixth input terminal to receive the second tap code.

In Example 6, the subject matter of Example 5 includes, wherein the first comparator circuit comprises a seventh input terminal to receive a first clock signal.

In Example 7, the subject matter of Example 6 includes, wherein the second comparator circuit comprises a seventh input terminal to receive a second clock signal.

In Example 8, the subject matter of Example 7 includes, wherein the first FF circuit comprises a second input terminal to receive a third clock signal.

In Example 9, the subject matter of Example 8 includes, wherein the second FF circuit comprises a second input terminal to receive a fourth clock signal.

In Example 10, the subject matter of Examples 7-9 includes, wherein the first SH circuit comprises a third input terminal to receive the first clock signal.

In Example 11, the subject matter of Example 10 includes, wherein the second SH circuit comprises a third input terminal to receive the second clock signal.

In Example 12, the subject matter of Examples 1-11 includes, wherein the second input terminal of the first SH circuit and the second input terminal of the second SH circuit are to receive a voltage reference signal.

In Example 13, the subject matter of Examples 1-12 includes, wherein the equalizer circuit comprises a system-on-chip (SoC), the SoC comprising an integrated circuit (IC), the IC comprising at least two of the first SH circuit, the second SH circuit, the first comparator circuit, the second comparator circuit, the first FF circuit, and the second FF circuit.

In Example 14, the subject matter of Example 13 includes, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

Example 15 is an apparatus comprising: a first sample-and-hold (SH) circuit to generate a first voltage signal pair based on an input voltage signal; a second SH circuit to generate a second voltage signal pair based on the input voltage signal; a first comparator circuit to generate a first output voltage signal based on the first voltage signal pair, a first feedback signal, and a second feedback signal; a first flip-flop (FF) circuit to generate a second output voltage signal based on the first output voltage signal, the second output voltage signal comprising the first feedback signal; and a second comparator circuit to generate a third output voltage signal based on the second voltage signal pair, the third output voltage signal comprising the second feedback signal.

In Example 16, the subject matter of Example 15 includes, wherein the second comparator circuit generates the third output voltage signal further based on a third feedback signal and a fourth feedback signal, wherein the first SH circuit generates the first voltage signal pair at least based on a first clock signal, and wherein the first SH circuit is configured to: limit a conversion phase delay associated with the first clock signal; narrow a reset phase of the first clock signal; and generate a hold phase of the first clock signal based on the narrowing of the reset phase.

In Example 17, the subject matter of Example 16 includes, a second FF circuit to generate a fourth output voltage signal based on the third output voltage signal, the fourth output voltage signal comprising the third feedback signal.

In Example 18, the subject matter of Examples 16-17 includes, wherein the first output voltage signal comprises the fourth feedback signal.

In Example 19, the subject matter of Examples 15-18 includes, wherein the first comparator circuit comprises a first pair of integration nodes and at least a first capacitive digital-to-analog converter (DAC) circuit coupled to the first pair of integration nodes.

In Example 20, the subject matter of Example 19 includes, wherein the first comparator circuit is to: receive one or more tap codes; and adjust capacitance of the at least a first capacitive DAC circuit between the first pair of integration nodes based on the one or more tap codes.

In Example 21, the subject matter of Example 20 includes, wherein the second comparator circuit comprises a second pair of integration nodes and at least a second capacitive DAC circuit coupled to the second pair of integration nodes.

In Example 22, the subject matter of Example 21 includes, wherein the second comparator circuit is to: receive the one or more tap codes; and adjust capacitance of the at least a second capacitive DAC circuit between the second pair of integration nodes based on the one or more tap codes.

In Example 23, the subject matter of Examples 17-22 includes, wherein the apparatus comprises a system-on-chip (SoC), the SoC comprising an integrated circuit (IC), the IC comprising at least two of the first SH circuit, the second SH circuit, the first comparator circuit, the second comparator circuit, the first FF circuit, and the second FF circuit.

In Example 24, the subject matter of Example 23 includes, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

Example 25 is a method for signal equalization, the method comprising: generating a first voltage signal pair and a second voltage signal pair based on an input voltage signal; generating a first output voltage signal based on the first voltage signal pair, a first feedback signal, and a second feedback signal; generating a first equalized signal based on the first output voltage signal, the first equalized signal comprising the first feedback signal; and generating a second output voltage signal based on the second voltage signal pair, the second output voltage signal comprising the second feedback signal.

In Example 26, the subject matter of Example 25 includes, generating the second output voltage signal further based on a third feedback signal and a fourth feedback signal; generating a second equalized voltage signal based on the second output voltage signal, the second equalized voltage signal comprising the third feedback signal, and the first output voltage signal comprising the fourth feedback signal.

Example 27 is at least one machine-readable medium, including instructions that, when executed by processing circuitry, cause the processing circuitry to perform operations to implement any of Examples 1-26.

Example 28 is an apparatus comprising means to implement any of Examples 1-26.

Example 29 is a system to implement any of Examples 1-26.

Example 30 is a method to implement any of Examples 1-26.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An equalizer circuit comprising:
a first sample-and-hold (SH) circuit comprising a first input terminal and a second input terminal, the first input terminal of the first SH circuit to receive an input voltage signal;
a second SH circuit comprising a first input terminal and a second input terminal, the first input terminal of the second SH circuit to receive the input voltage signal;
a first comparator circuit comprising a first input terminal coupled to a first output terminal of the first SH circuit and a second input terminal coupled to a second output terminal of the first SH circuit;
a second comparator circuit comprising a first input terminal coupled to a first output terminal of the second SH circuit and a second input terminal coupled to a second output terminal of the second SH circuit;
a first flip-flop (FF) circuit comprising a first input terminal coupled to an output terminal of the first SH circuit, and an output terminal coupled to a third input terminal of the first comparator circuit; and
a second FF circuit comprising a first input terminal coupled to an output terminal of the second SH circuit, and an output terminal coupled to a third input terminal of the second comparator circuit.

2. The equalizer circuit of claim 1, wherein an output terminal of the first comparator circuit is coupled to a fourth input terminal of the second comparator circuit.

3. The equalizer circuit of claim 2, wherein an output terminal of the second comparator circuit is coupled to a fourth input terminal of the first comparator circuit.

4. The equalizer circuit of claim 3, wherein the first comparator circuit comprises a fifth input terminal to receive a first tap code and a sixth input terminal to receive a second tap code.

5. The equalizer circuit of claim 4, wherein the second comparator circuit comprises a fifth input terminal to receive the first tap code and a sixth input terminal to receive the second tap code.

6. The equalizer circuit of claim 5, wherein the first comparator circuit comprises a seventh input terminal to receive a first clock signal.

7. The equalizer circuit of claim 6, wherein the second comparator circuit comprises a seventh input terminal to receive a second clock signal.

8. The equalizer circuit of claim 7, wherein the first FF circuit comprises a second input terminal to receive a third clock signal.

9. The equalizer circuit of claim 8, wherein the second FF circuit comprises a second input terminal to receive a fourth clock signal.

10. The equalizer circuit of claim 7, wherein the first SH circuit comprises a third input terminal to receive the first clock signal.

11. The equalizer circuit of claim 10, wherein the second SH circuit comprises a third input terminal to receive the second clock signal.

12. The equalizer circuit of claim 1, wherein the equalizer circuit comprises a system-on-chip (SoC), the SoC comprising an integrated circuit (IC), the IC comprising at least two of the first SH circuit, the second SH circuit, the first comparator circuit, the second comparator circuit, the first FF circuit, and the second FF circuit.

13. The equalizer circuit of claim 12, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

14. An apparatus comprising:
a first sample-and-hold (SH) circuit to generate a first voltage signal pair based on an input voltage signal;
a second SH circuit to generate a second voltage signal pair based on the input voltage signal;
a first comparator circuit to generate a first output voltage signal based on the first voltage signal pair, a first feedback signal, and a second feedback signal;
a first flip-flop (FF) circuit to generate a second output voltage signal based on the first output voltage signal, the second output voltage signal comprising the first feedback signal; and
a second comparator circuit to generate a third output voltage signal based on the second voltage signal pair, the third output voltage signal comprising the second feedback signal.

15. The apparatus of claim 14, wherein the second comparator circuit generates the third output voltage signal further based on a third feedback signal and a fourth feedback signal, wherein the first SH circuit generates the first voltage signal pair at least based on a first clock signal, and wherein the first SH circuit is configured to limit the first clock signal to at least a 25% duty cycle based on performing:
limiting a conversion phase delay associated with the first clock signal;
narrowing a reset phase of the first clock signal; and
generating a hold phase of the first clock signal based on the narrowing of the reset phase.

16. The apparatus of claim 15, further comprising:
a second FF circuit to generate a fourth output voltage signal based on the third output voltage signal, the fourth output voltage signal comprising the third feedback signal.

17. The apparatus of claim 15, wherein the first output voltage signal comprises the fourth feedback signal.

18. The apparatus of claim 14, wherein the first comparator circuit comprises a first pair of integration nodes and at least a first capacitive digital-to-analog converter (DAC) circuit coupled to the first pair of integration nodes.

19. The apparatus of claim 18, wherein the first comparator circuit is to:
receive one or more tap codes; and
adjust capacitance of the at least a first capacitive DAC circuit between the first pair of integration nodes based on the one or more tap codes.

20. A method for manufacturing an equalizer circuit, comprising:
generating a first voltage signal pair and a second voltage signal pair based on an input voltage signal;
generating a first output voltage signal based on the first voltage signal pair, a first feedback signal, and a second feedback signal;
generating a second output voltage signal based on the second voltage signal pair, the second output voltage signal comprising the second feedback signal; and
generating a first equalized signal based on the first output voltage signal, the first equalized signal comprising the first feedback signal.
